(19) United States
(12) Patent Application Publication
(10) Pub. No.: US 2022/0045660 A1
(43) Pub. Date: Feb. 10, 2022

(54) CABLE TELEVISION SIGNAL SPLITTING APPARATUS

(71) Applicant: CABLE VISION ELECTRONICS CO., LTD, New Taipei City (TW)

(72) Inventors: Chien-Chung LEE, New Taipei City (TW); Chiang-Po YANG, New Taipei City (TW); Mao-Peng YU, New Taipei City (TW)

(21) Appl. No.: 17/031,293

(22) Filed: Sep. 24, 2020

(30) Foreign Application Priority Data
Aug. 6, 2020 (TW) 109210171

(51) Int. Cl. H03H 7/48; H04N 7/10; H04N 7/173

(52) U.S. Cl. CPC H03H 7/482; H04N 7/17309; H04N 7/104

(57) ABSTRACT

A cable television signal splitting apparatus transmits a cable television system downstream signal and a cable television system upstream signal. The cable television signal splitting apparatus includes a splitter, a bi-directional amplifying circuit and a splitting circuit. The bi-directional amplifying circuit is electrically connected to the splitter. The splitting circuit is electrically connected to the bi-directional amplifying circuit. The bi-directional amplifying circuit is arranged between the splitter and the splitting circuit. The splitter receives the cable television system downstream signal and transmits the cable television system downstream signal to the bi-directional amplifying circuit. The splitting circuit receives the cable television system upstream signal and transmits the cable television system upstream signal to the bi-directional amplifying circuit.

### BACKGROUND OF THE INVENTION

### Field of the Invention

The present invention relates to a signal splitting apparatus, and especially relates to a cable television signal splitting apparatus.

### Description of the Related Art

Currently, the cable television system is very popular. The cable television system transmits the television programs and the network signals to the client sides through the coaxial cables.

The cable television system needs to use the related art diplexer to filter the cable television system downstream signal and the cable television system upstream signal. However, with the increment of the frequency band used in the cable television system, the related art diplexer has to be changed; this will increase the maintenance cost of the cable television system.

### SUMMARY OF THE INVENTION

In order to solve the above-mentioned problems, an object of the present invention is to provide a cable television signal splitting apparatus.

In order to achieve the object of the present invention mentioned above, the cable television signal splitting apparatus of the present invention is configured to transmit a cable television system downstream signal and a cable television system upstream signal. The cable television signal splitting apparatus comprises a splitter, a bi-directional amplifying circuit and a splitting circuit. The bi-directional amplifying circuit is electrically connected to the splitter. The splitting circuit is electrically connected to the bi-directional amplifying circuit. Moreover, the bi-directional amplifying circuit is arranged between the splitter and the splitting circuit. The splitter is configured to receive the cable television system downstream signal and transmit the cable television system downstream signal to the bi-directional amplifying circuit. The splitting circuit is configured to receive the cable television system upstream signal and transmit the cable television system upstream signal to the bi-directional amplifying circuit.

Moreover, in an embodiment of the cable television signal splitting apparatus of the present invention mentioned above, the bi-directional amplifying circuit comprises a downstream amplifier and an upstream amplifier. The downstream amplifier is electrically connected to the splitter and the splitting circuit. The upstream amplifier is electrically connected to the splitter and the splitting circuit.

Moreover, in an embodiment of the cable television signal splitting apparatus of the present invention mentioned above, the splitting circuit comprises a downstream splitter and an upstream splitter. The downstream splitter is electrically connected to the downstream amplifier. The upstream splitter is electrically connected to the upstream amplifier.

Moreover, in an embodiment of the cable television signal splitting apparatus of the present invention mentioned above, the cable television signal splitting apparatus of the present invention further comprises a plurality of signal splitting-combining units electrically connected to the downstream splitter and the upstream splitter, wherein the signal splitting-combining units are configured to receive the cable television system upstream signal and transmit the cable television system upstream signal to the splitting circuit.

Moreover, in an embodiment of the cable television signal splitting apparatus of the present invention mentioned above, the signal splitting-combining units are a plurality of signal splitters.

Moreover, in an embodiment of the cable television signal splitting apparatus of the present invention mentioned above, the signal splitting-combining units are a plurality of directional couplers.

Moreover, in an embodiment of the cable television signal splitting apparatus of the present invention mentioned above, the cable television signal splitting apparatus of the present invention further comprises a plurality of terminal matching units electrically connected to the signal splitting-combining units.

Moreover, in an embodiment of the cable television signal splitting apparatus of the present invention mentioned above, each of the terminal matching units is, for example but not limited to, a 4.3 ohm resistor.

Moreover, in an embodiment of the cable television signal splitting apparatus of the present invention mentioned above, the cable television signal splitting apparatus of the present invention further comprises a diplexer and a matching component. The diplexer is electrically connected to the downstream amplifier. The matching component is electrically connected to the diplexer. Moreover, the diplexer comprises a high-pass part and a low-pass part. The high-pass part is electrically connected to the downstream amplifier. The low-pass part is electrically connected to the matching component. Moreover, the diplexer is configured to match the downstream amplifier. The diplexer is arranged between the splitter and the downstream amplifier, or between the downstream amplifier and the downstream splitter. The matching component is configured to match the low-pass part.

Moreover, in an embodiment of the cable television signal splitting apparatus of the present invention mentioned above, the diplexer further comprises a matching inductor, a matching capacitor and a matching resistor. The matching inductor is electrically connected to the high-pass part and the low-pass part. The matching capacitor is electrically connected to the matching inductor. The matching resistor is electrically connected to the matching capacitor. Moreover, the matching inductor, the matching capacitor and the matching resistor are connected to each other in series. The matching inductor, the matching capacitor and the matching resistor are configured to match a mismatch frequency band of the high-pass part and the low-pass part.

Moreover, in an embodiment of the cable television signal splitting apparatus of the present invention mentioned above, a low-pass frequency band of the diplexer is, for example but not limited to, below 42 MHz. A high-pass frequency band of the diplexer is, for example but not limited to, above 54 MHz.

Moreover, in an embodiment of the cable television signal splitting apparatus of the present invention mentioned above, the mismatch frequency band is, for example but not limited to, 42 MHz˜54 MHz.

Moreover, in an embodiment of the cable television signal splitting apparatus of the present invention mentioned above, the matching component is, for example but not limited to, a 75 ohm resistor.

Moreover, in an embodiment of the cable television signal splitting apparatus of the present invention mentioned above, the matching resistor is, for example but not limited to, a 75 ohm resistor.

Moreover, in an embodiment of the cable television signal splitting apparatus of the present invention mentioned above, the cable television signal splitting apparatus of the present invention further comprises a diplexer and a matching component. The diplexer is electrically connected to the upstream amplifier. The matching component is electrically connected to the diplexer. Moreover, the diplexer comprises a low-pass part and a high-pass part. The low-pass part is electrically connected to the upstream amplifier. The high-pass part is electrically connected to the matching component. Moreover, the diplexer is configured to match the upstream amplifier. The diplexer is arranged between the splitter and the upstream amplifier, or between the upstream amplifier and the upstream splitter. The matching component is configured to match the high-pass part.

Moreover, in an embodiment of the cable television signal splitting apparatus of the present invention mentioned above, the diplexer further comprises a matching inductor, a matching capacitor and a matching resistor. The matching inductor is electrically connected to the high-pass part and the low-pass part. The matching capacitor is electrically connected to the matching inductor. The matching resistor is electrically connected to the matching capacitor. Moreover, the matching inductor, the matching capacitor and the matching resistor are connected to each other in series. The matching inductor, the matching capacitor and the matching resistor are configured to match a mismatch frequency band of the high-pass part and the low-pass part.

Moreover, in an embodiment of the cable television signal splitting apparatus of the present invention mentioned above, a low-pass frequency band of the diplexer is, for example but not limited to, below 204 MHz. A high-pass frequency band of the diplexer is, for example but not limited to, above 258 MHz.

Moreover, in an embodiment of the cable television signal splitting apparatus of the present invention mentioned above, the mismatch frequency band is, for example but not limited to, 204 MHz˜258 MHz.

Moreover, in an embodiment of the cable television signal splitting apparatus of the present invention mentioned above, the matching component is, for example but not limited to, a 75 ohm resistor.

Moreover, in an embodiment of the cable television signal splitting apparatus of the present invention mentioned above, the matching resistor is, for example but not limited to, a 75 ohm resistor.

The advantage of the present invention is to reduce the maintenance cost of the cable television system. Namely, the present invention can be applied to various upstream/downstream frequency bands, for examples, 42 MHz/54 MHz, 65 MHz/85 MHz, 85 MHz/102 MHz and 204 MHz/258 MHz. For another example, the client can upgrade 42 MHz/54 MHz to 204 MHz/258 MHz without changing the diplexer; the splitting apparatus does not need to be changed either, so that the upgrade cost or the maintenance cost of the cable television system can be reduced.

Please refer to the detailed descriptions and figures of the present invention mentioned below for further understanding the technology, method and effect of the present invention achieving the predetermined purposes. It believes that the purposes, characteristic and features of the present invention can be understood deeply and specifically. However, the figures are only for references and descriptions, but the present invention is not limited by the figures.

### BRIEF DESCRIPTION OF DRAWINGS

FIG. 1 shows a circuit block diagram of the first embodiment of the cable television signal splitting apparatus of the present invention.

FIG. 2 shows a circuit block diagram of the second embodiment of the cable television signal splitting apparatus of the present invention.

FIG. 3 shows a circuit block diagram of the third embodiment of the cable television signal splitting apparatus of the present invention.

FIG. 4 shows a circuit block diagram of the fourth embodiment of the cable television signal splitting apparatus of the present invention.

FIG. 5 shows a circuit block diagram of the fifth embodiment of the cable television signal splitting apparatus of the present invention.

FIG. 6 shows a circuit diagram of an embodiment of the diplexer of the present invention.

### DETAILED DESCRIPTION OF THE INVENTION

In the present disclosure, numerous specific details are provided, to provide a thorough understanding of embodiments of the invention. Persons of ordinary skill in the art will recognize, however, that the present invention can be practiced without one or more of the specific details. In other instances, well-known details are not shown or described to avoid obscuring aspects of the present invention. Now please refer to the figures for the explanation of the technical content and the detailed description of the present invention:

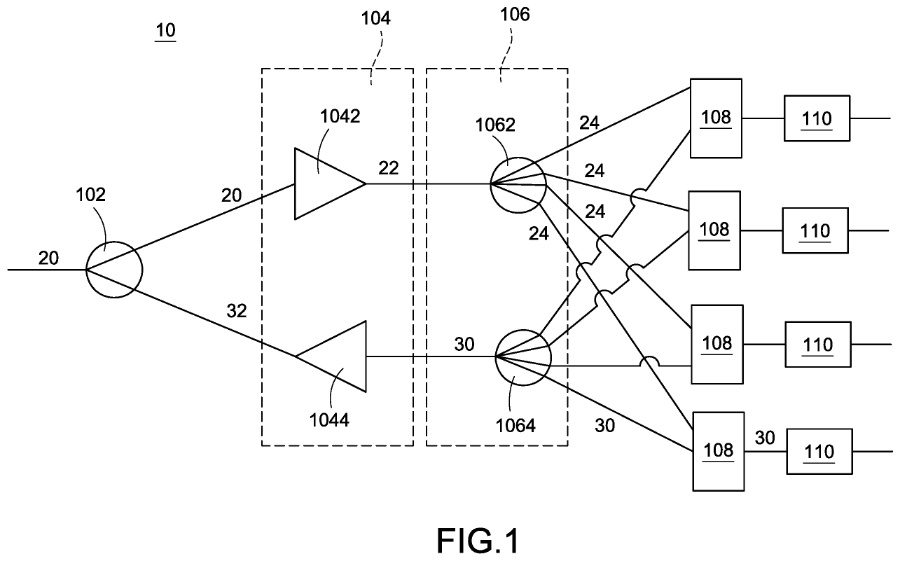

FIG. 1 shows a circuit block diagram of the first embodiment of the cable television signal splitting apparatus of the present invention. The cable television signal splitting apparatus 10 of the present invention is configured to transmit a cable television system downstream signal 20 and a cable television system upstream signal 30. The cable television signal splitting apparatus 10 comprises a splitter 102, a bi-directional amplifying circuit 104, a splitting circuit 106, a plurality of signal splitting-combining units 108 and a plurality of terminal matching units 110. The bi-directional amplifying circuit 104 comprises a downstream amplifier 1042 and an upstream amplifier 1044. The splitting circuit 106 comprises a downstream splitter 1062 and an upstream splitter 1064. The components mentioned above are electrically connected to each other, and the bi-directional amplifying circuit 104 is arranged between the splitter 102 and the splitting circuit 106.

The splitter 102 is configured to receive the cable television system downstream signal 20 and transmit the cable television system downstream signal 20 to the bi-directional amplifying circuit 104. The signal splitting-combining units 108 are configured to receive the cable television system upstream signal 30 and transmit the cable television system upstream signal 30 to the splitting circuit 106. The splitting circuit 106 is configured to receive the cable television system upstream signal 30 and transmit the cable television system upstream signal 30 to the bi-directional amplifying circuit 104. The signal splitting-combining units 108 are a plurality of signal splitters or a plurality of directional couplers. Each of the terminal matching units 110 is, for example but not limited to, a 4.3 ohm resistor.

Moreover, the downstream amplifier 1042 is configured to receive the cable television system downstream signal 20 and amplify the cable television system downstream signal 20 to obtain an amplified downstream signal 22. The downstream amplifier 1042 is configured to transmit the amplified downstream signal 22 to the splitting circuit 106. The upstream amplifier 1044 is configured to receive the cable television system upstream signal 30 and amplify the cable television system upstream signal 30 to obtain an amplified upstream signal 32. The upstream amplifier 1044 is configured to transmit the amplified upstream signal 32 to the splitter 102. Moreover, the downstream splitter 1062 is configured to receive the amplified downstream signal 22 and split the amplified downstream signal 22 into a plurality of split downstream signals 24. The upstream splitter 1064 is configured to receive the cable television system upstream signal 30 and transmit the cable television system upstream signal 30 to the upstream amplifier 1044. Moreover, the downstream splitter 1062 is configured to transmit the split downstream signals 24 to the signal splitting-combining units 108 respectively. The signal splitting-combining units 108 are configured to receive the cable television system upstream signal 30 and transmit the cable television system upstream signal 30 to the upstream splitter 1064.

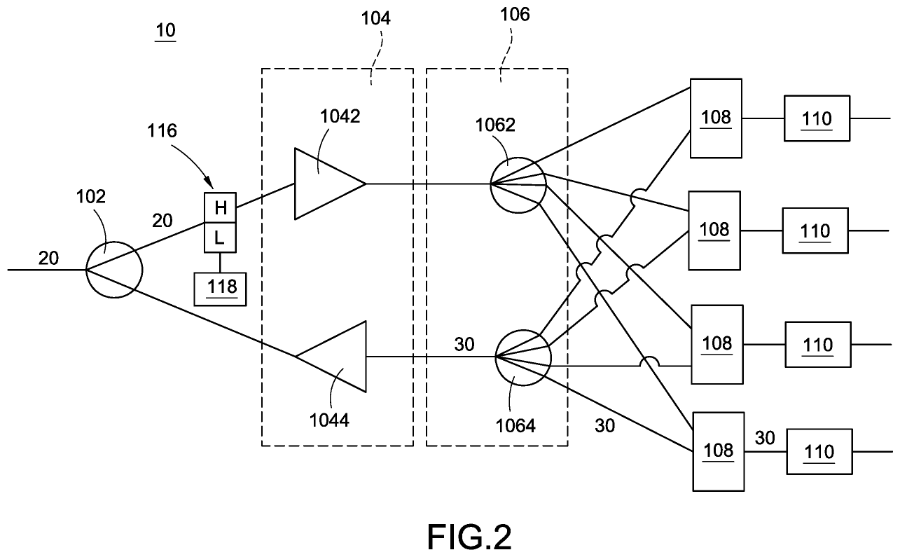

FIG. 2 shows a circuit block diagram of the second embodiment of the cable television signal splitting apparatus of the present invention. The descriptions of the elements shown in FIG. 2 which are the same as the elements shown in FIG. 1 are not repeated here for brevity. The cable television signal splitting apparatus 10 of the present invention further comprises a diplexer 116 and a matching component 118. The diplexer 116 comprises a high-pass part H (namely, a high-pass circuit) and a low-pass part L (namely, a low-pass circuit). The components mentioned above are electrically connected to each other, and the diplexer 116 is arranged between the splitter 102 and the downstream amplifier 1042. The diplexer 116 is configured to match the downstream amplifier 1042. The matching component 118 is configured to match the low-pass part L. The matching component 118 is, for example but not limited to, a 75 ohm resistor. A low-pass frequency band of the diplexer 116 is, for example but not limited to, below 42 MHz. A high-pass frequency band of the diplexer 116 is, for example but not limited to, above 54 MHz.

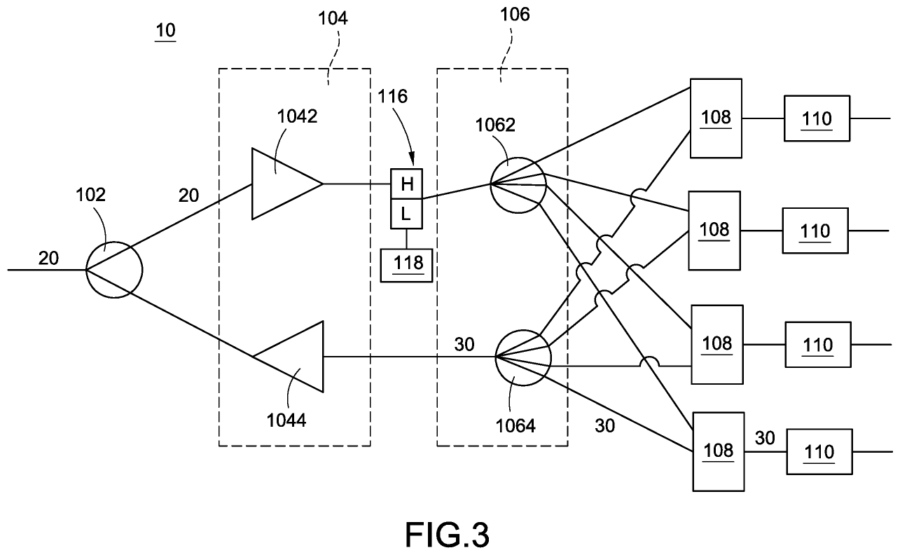

FIG. 3 shows a circuit block diagram of the third embodiment of the cable television signal splitting apparatus of the present invention. The descriptions of the elements shown in FIG. 3 which are the same as the elements shown in the figures mentioned above are not repeated here for brevity. The diplexer 116 is arranged between the downstream amplifier 1042 and the downstream splitter 1062.

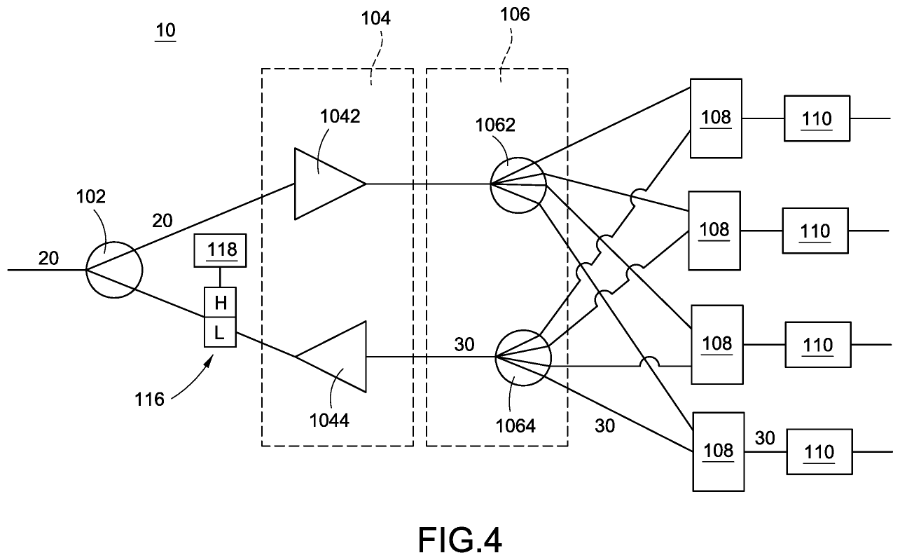

FIG. 4 shows a circuit block diagram of the fourth embodiment of the cable television signal splitting apparatus of the present invention. The descriptions of the elements shown in FIG. 4 which are the same as the elements shown in the figures mentioned above are not repeated here for brevity. The diplexer 116 is arranged between the splitter 102 and the upstream amplifier 1044. The diplexer 116 is configured to match the upstream amplifier 1044. The matching component 118 is configured to match the high-pass part H. A low-pass frequency band of the diplexer 116 is, for example but not limited to, below 204 MHz. A high-pass frequency band of the diplexer 116 is, for example but not limited to, above 258 MHz.

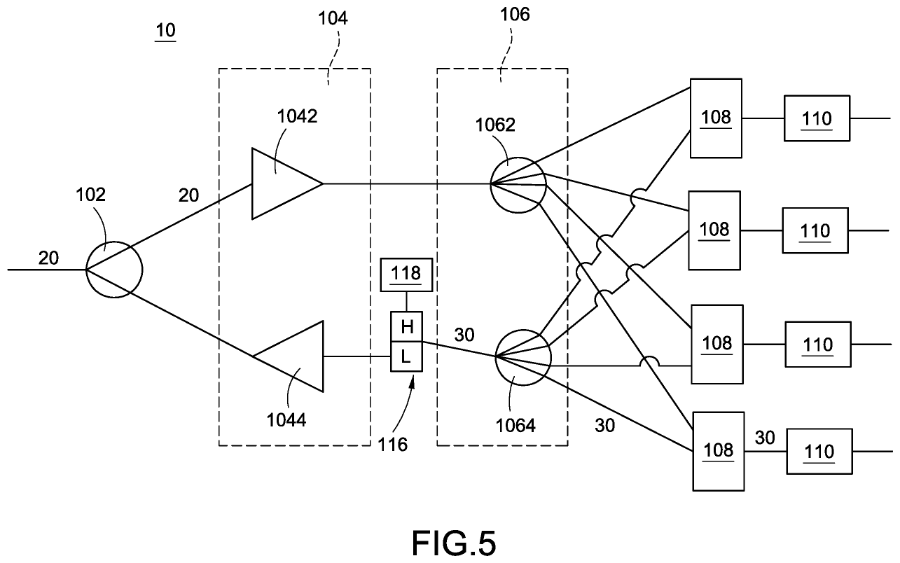

FIG. 5 shows a circuit block diagram of the fifth embodiment of the cable television signal splitting apparatus of the present invention. The descriptions of the elements shown in FIG. 5 which are the same as the elements shown in the figures mentioned above are not repeated here for brevity. The diplexer 116 is arranged between the upstream amplifier 1044 and the upstream splitter 1064.

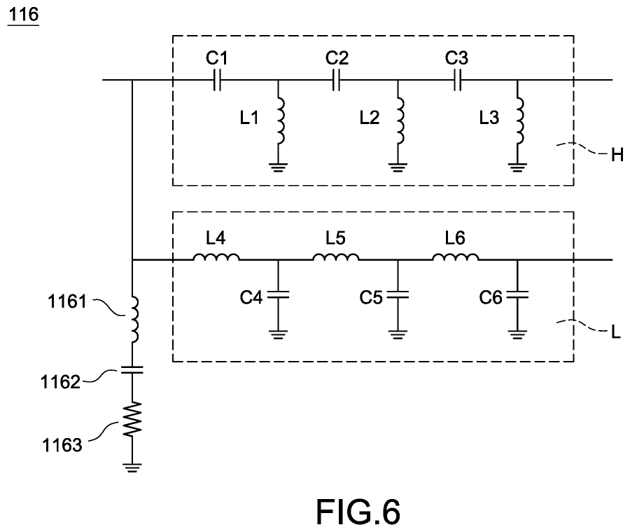

FIG. 6 shows a circuit diagram of an embodiment of the diplexer of the present invention. The descriptions of the elements shown in FIG. 6 which are the same as the elements shown in the figures mentioned above are not repeated here for brevity. The diplexer 116 further comprises a matching inductor 1161, a matching capacitor 1162 and a matching resistor 1163. The components mentioned above are electrically connected to each other, and the matching resistor 1163 is, for example but not limited to, a 75 ohm resistor. The matching inductor 1161, the matching capacitor 1162 and the matching resistor 1163 are connected to each other in series. The matching inductor 1161, the matching capacitor 1162 and the matching resistor 1163 are configured to match a mismatch frequency band of the high-pass part H and the low-pass part L. For FIG. 2 and FIG. 3, the mismatch frequency band is, for example but not limited to, 42 MHz˜54 MHz. For FIG. 4 and FIG. 5, the mismatch frequency band is, for example but not limited to, 204 MHz˜258 MHz.

Moreover, the high-pass part H comprises a first filter capacitor C1, a second filter capacitor C2, a third filter capacitor C3, a first filter inductor L1, a second filter inductor L2 and a third filter inductor L3. The low-pass part L comprises a fourth filter inductor L4, a fifth filter inductor L5, a sixth filter inductor L6, a fourth filter capacitor C4, a fifth filter capacitor C5 and a sixth filter capacitor C6. The components mentioned above are electrically connected to each other.

The advantage of the present invention is to reduce the maintenance cost of the cable television system. Namely, the present invention can be applied to various upstream/downstream frequency bands, for examples, 42 MHz/54 MHz, 65 MHz/85 MHz, 85 MHz/102 MHz and 204 MHz/258 MHz. For another example, the client can upgrade 42 MHz/54 MHz to 204 MHz/258 MHz without changing the diplexer; the splitting apparatus does not need to be changed either, so that the upgrade cost or the maintenance cost of the cable television system can be reduced.

Although the present invention has been described with reference to the preferred embodiment thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

1. A cable television signal splitting apparatus configured to transmit a cable television system downstream signal and a cable television system upstream signal, the cable television signal splitting apparatus comprising:
a splitter;
a bi-directional amplifying circuit electrically connected to the splitter; and
a splitting circuit electrically connected to the bi-directional amplifying circuit,
wherein the bi-directional amplifying circuit is arranged between the splitter and the splitting circuit; the splitter is configured to receive the cable television system downstream signal and transmit the cable television system downstream signal to the bi-directional amplifying circuit; the splitting circuit is configured to receive the cable television system upstream signal and transmit the cable television system upstream signal to the bi-directional amplifying circuit
wherein the bi-directional amplifying circuit comprises:
a downstream amplifier electrically connected to the splitter and the splitting circuit and
an upstream amplifier electrically connected to the splitter and the splitting circuit
wherein the splitting circuit comprises:
a downstream splitter electrically connected to the downstream amplifier; and
an upstream splitter electrically connected to the upstream amplifier, wherein the downstream splitter and the upstream splitter are different splitters;
the cable television signal splitting apparatus further comprising:
a plurality of signal splitting-combining units,
wherein the signal splitting-combining units are configured to receive the cable television system upstream signal and transmit the cable television system upstream signal to the splitting circuit;
wherein each of the signal splitting-combining units is electrically connected to both the downstream splitter and the upstream splitter through different paths;
wherein both of the downstream splitter and the upstream splitter are arranged between the splitter and the signal splitting-combining units.

2-4. (canceled)

5. The cable television signal splitting apparatus of claim 1, wherein the signal splitting-combining units are a plurality of signal splitters.

6. The cable television signal splitting apparatus of claim 1, wherein the signal splitting-combining units are a plurality of directional couplers.

7. The cable television signal splitting apparatus of claim 1, further comprising:
a plurality of terminal matching units electrically connected to the signal splitting-combining units.

8. The cable television signal splitting apparatus of claim 7, wherein each of the terminal matching units is a 4.3 ohm resistor.

9. The cable television signal splitting apparatus of claim 1, further comprising:
a diplexer electrically connected to the downstream amplifier; and
a matching component electrically connected to the diplexer,
wherein the diplexer comprises:
a high-pass part electrically connected to the downstream amplifier; and
a low-pass part electrically connected to the matching component,
wherein the diplexer is configured to match the downstream amplifier; the diplexer is arranged between the splitter and the downstream amplifier, or between the downstream amplifier and the downstream splitter; the matching component is configured to match the low-pass part.

10. The cable television signal splitting apparatus of claim 9, wherein the diplexer further comprises:
a matching inductor electrically connected to the high-pass part and the low-pass part;
a matching capacitor electrically connected to the matching inductor; and
a matching resistor electrically connected to the matching capacitor,
wherein the matching inductor, the matching capacitor and the matching resistor are connected to each other in series; the matching inductor, the matching capacitor and the matching resistor are configured to match a mismatch frequency band of the high-pass part and the low-pass part.

11. The cable television signal splitting apparatus of claim 9, wherein a low-pass frequency band of the diplexer is below 42 MHz; a high-pass frequency band of the diplexer is above 54 MHz.

12. The cable television signal splitting apparatus of claim 10, wherein the mismatch frequency band is 42 MHz˜54 MHz.

13. The cable television signal splitting apparatus of claim 9, wherein the matching component is a 75 ohm resistor.

14. The cable television signal splitting apparatus of claim 10, wherein the matching resistor is a 75 ohm resistor.

15. The cable television signal splitting apparatus of claim 1, further comprising:
a diplexer electrically connected to the upstream amplifier; and
a matching component electrically connected to the diplexer,
wherein the diplexer comprises:
a low-pass part electrically connected to the upstream amplifier; and
a high-pass part electrically connected to the matching component,
wherein the diplexer is configured to match the upstream amplifier; the diplexer is arranged between the splitter and the upstream amplifier, or between the upstream amplifier and the upstream splitter; the matching component is configured to match the high-pass part.

16. The cable television signal splitting apparatus of claim 15, wherein the diplexer further comprises:
a matching inductor electrically connected to the high-pass part and the low-pass part;
a matching capacitor electrically connected to the matching inductor; and
a matching resistor electrically connected to the matching capacitor,
wherein the matching inductor, the matching capacitor and the matching resistor are connected to each other in series; the matching inductor, the matching capacitor and the matching resistor are configured to match a mismatch frequency band of the high-pass part and the low-pass part.

17. The cable television signal splitting apparatus of claim 15, wherein a low-pass frequency band of the diplexer is below 204 MHz; a high-pass frequency band of the diplexer is above 258 MHz.

18. The cable television signal splitting apparatus of claim 16, wherein the mismatch frequency band is 204 MHz˜258 MHz.

19. The cable television signal splitting apparatus of claim 15, wherein the matching component is a 75 ohm resistor.

20. The cable television signal splitting apparatus of claim 16, wherein the matching resistor is a 75 ohm resistor.
